(19) United States
(12) Patent Application Publication
(10) Pub. No.: US 2026/0334146 A1
(43) Pub. Date: Oct. 22, 2026

(54) SUBSTRATE STORAGE CONTAINER

(71) Applicant: MIRAIAL CO., LTD., Tokyo (JP)

(72) Inventor: Kouji KUBOTA, Tokyo (JP)

(21) Appl. No.: 19/491,148

(22) PCT Filed: Jun. 9, 2023
(86) PCT No.: PCT/JP2023/021559

§ 371 Date: Dec. 8, 2025

(51) Int. Cl. H10P 72/10

(52) U.S. Cl. CPC H10P 72/1921

(57) ABSTRACT

A substrate storage container comprises: a container body; a lid body; and a lid-body-side substrate support part capable of supporting an edge part of a plurality of substrates. The lid-body-side substrate support part has an upper-side inclined surface and a lower-side inclined surface that form a V-shaped groove, which is a recessed groove depressed away from the center of a substrate storage space. A frontmost part of the upper-side inclined surface and the lower-side inclined surface functions as a holding part for holding the edge part of the plurality of substrates. The lower-side inclined surface has a holding surface forming the holding part and a guide surface which is located rearward from the holding surface and which guides the substrates to the holding part while causing the substrates to slide. A guide inclination angle, by which the guide surface is inclined with respect to a front direction, decreases in multiple stages.

### TECHNICAL FIELD

The present invention relates to a substrate storing container for use in, for example, storing, keeping, conveying, and transporting a substrate composed of a semiconductor wafer or the like.

### BACKGROUND ART

As a container for storing and transporting a substrate composed of a semiconductor wafer, a substrate storing container including a container body and a lid has been conventionally known (see, for example, Patent Document 1).

The container body has, at one end thereof, an opening peripheral edge portion that defines a container body opening. The other end of the container body has a closed tubular wall. The container body has a substrate storing space formed therein. The substrate storing space is formed by being surrounded by the wall and can store a plurality of substrates. The lid is attachable to and detachable from the opening peripheral edge portion and can close the container body opening. In the substrate storing space, lateral substrate supports are provided on the wall so as to form counterparts to each in the left-right direction. When the container body opening is not closed with the lid, the lateral substrate supports can support edges of the plurality of substrates in a state in which the substrates adjacent to each other in the upward-downward direction are arranged in parallel and spaced apart from each other by a predetermined interval.

A front retainer is provided on a portion of the lid that faces the substrate storing space when the container body opening is closed with the lid. The front retainer has lid-side substrate supports that directly contact with the substrates and support the substrates, and has a lid-side leg that supports the lid-side substrate supports. The lid-side substrate supports can support edges of the plurality of substrates when the container body opening is closed with the lid. Furthermore, a back-side substrate support is provided so as to form a counterpart to the front retainer. The back-side substrate support can support edges of the plurality of substrates. When the container body opening is closed with the lid, the back-side substrate support cooperates with the front retainer to support and hold the plurality of substrates in a state in which the substrates adjacent to each other in the upward-downward direction are arranged in parallel and spaced apart from each other by a predetermined interval.

Each lid-side substrate support has an upper inclined surface and a lower inclined surface that form a V-shaped groove, which is a concave groove recessed away from the center of the substrate storing space (concave toward the forward side). The foremost portions of the upper inclined surface and the lower inclined surface function as a clamping portion that clamps the edge of a corresponding one of the plurality of substrates.

### CITATION LIST

### Patent Documents

Patent Document 1: Japanese Unexamined Patent Application (Translation of PCT Application), Publication No. 2013-540372

### DISCLOSURE OF THE INVENTION

### Problems to be Solved by the Invention

When the container body opening is closed with the lid, it is likely that the substrate fails to be guided into the clamping portion of the V-shaped groove of the lid-side substrate support. Specifically, the edges of the substrate are supported by the lateral substrate supports in a state in which the container body is disposed horizontally (a state in which the lower inclined surface of the lid-side substrate support is on the downward side). Thereafter, when the lid is brought closer to the container body opening of the container body, the substrate abuts against the lower inclined surface of the lid body-side substrate support, and then slides up along the lower inclined surface to be guided (introduced) into the clamping portion of the V-shaped groove.

However, there may be a case in which diverse variations, such as variations of the position and angle of the substrate supported on the lateral substrate supports (with respect to the lid-side substrate support) and bend in the substrate due to the thickness and weight of the substrate, prevent the substrate from smoothly sliding up along the lower inclined surface of the lid-side substrate support to be guided into the clamping portion of the V-shaped groove.

An object of the present invention is to provide a substrate storing container capable of preventing or reducing a failure to guide a substrate to a lid-side substrate support.

### Means for Solving the Problems

(1) A first aspect of the present invention relates to a substrate storing container including: a container body including a tubular wall one end of which is on a forward side and has a container body opening, and another end of which is on a rearward side and closed, the container body having a substrate storing space formed therein, the substrate storing space being defined by an inner surface of the wall, capable of storing a plurality of substrates, and communicating with the container body opening; a lid attachable to and detachable from the container body opening and capable of closing the container body opening; lid-side substrate supports disposed on a portion of the lid that faces the substrate storing space when the container body opening is closed with the lid, the lid-side substrate supports being capable of supporting edges of the plurality of substrates when the container body opening is closed with the lid; and back-side substrate supports disposed so as to form counterparts to the lid-side substrate supports in the substrate storing space, and capable of supporting edges of the plurality of the substrates, the back-side substrate supports being configured to cooperate with the lid-side substrate supports to support the plurality of substrates in a state in which the edges of the plurality of substrates are parallel to each other in an upward-downward direction when the container body opening is closed with the lid. Each of the lid-side substrate supports has an upper inclined surface and a lower inclined surface that form a V-shaped groove as a concave groove recessed away from a center of the substrate storing space. A foremost portion of the upper inclined surface and a foremost portion of the lower inclined surface function as a clamping portion that clamps an edge of a corresponding substrate of the plurality of substrates. The lower inclined surface has a clamping surface that forms the clamping portion, and a guiding surface that is located more rearward on the rearward side than the clamping surface and guides the corresponding substrate to the clamping portion while allowing the corresponding substrate to slide thereon, and a guiding inclination angle that is inclined with respect to a forward direction of the guiding surface decreases gradually in multiple steps.
(2) According to a second aspect of the present invention, in the substrate storing container described above in (1), the guiding surface has a first guiding surface on the rearward side and a second guiding surface on the forward side of the first guiding surface, and the second guiding surface has a larger length than the first guiding surface in a forward-rearward direction.
(3) According to a third aspect of the present invention, in the substrate storing container described above in (2), the second guiding surface has a larger area than the first guiding surface.
(4) According to a fourth aspect of the present invention, in the substrate storing container described above in any one of (1) to (3), a virtual plane orthogonal to a pair of lid-side substrate supports adjacent to each other in the upward-downward direction passes through one or both of a lid-side substrate support on the upward side and a lid-side substrate support on a downward side.
(5) According to a fifth aspect of the present invention, in the substrate storing container described above in any one of (1) to (4), when the pair of lid-side substrate supports adjacent to each other in the upward-downward direction are viewed from the forward side, a lower end edge of the lower inclined surface of the lid-side substrate support on the upward side and an upper end edge of the upper inclined surface of the lid-side substrate support on the downward side are arranged in parallel and spaced apart from each other, and are inclined in the downward direction as approaching inward in a lateral direction.

### EFFECTS OF THE INVENTION

The present invention can provide a substrate storing container capable of preventing or reducing a failure to guide a substrate to a lid-side substrate support.

### BRIEF DESCRIPTION OF THE DRAWINGS

FIG. 1 is an exploded perspective view illustrating a state in which substrates W are stored in a substrate storing container 1 according to an embodiment of the present invention;

FIG. 2 is a perspective view illustrating a container body 2 in which the substrates W are not stored;

FIG. 3 is a perspective view illustrating a lid 3 having a front retainer 7 attached thereto;

FIG. 4A is a partial front view (as viewed in a forward direction D11) illustrating lid-side substrate supports 73 of the front retainer 7;

FIG. 4B is a partial enlarged view of FIG. 4A; and FIG. 5 is a cross-sectional view taken along line A-A in FIG. 4A.

### PREFERRED MODE FOR CARRYING OUT THE INVENTION

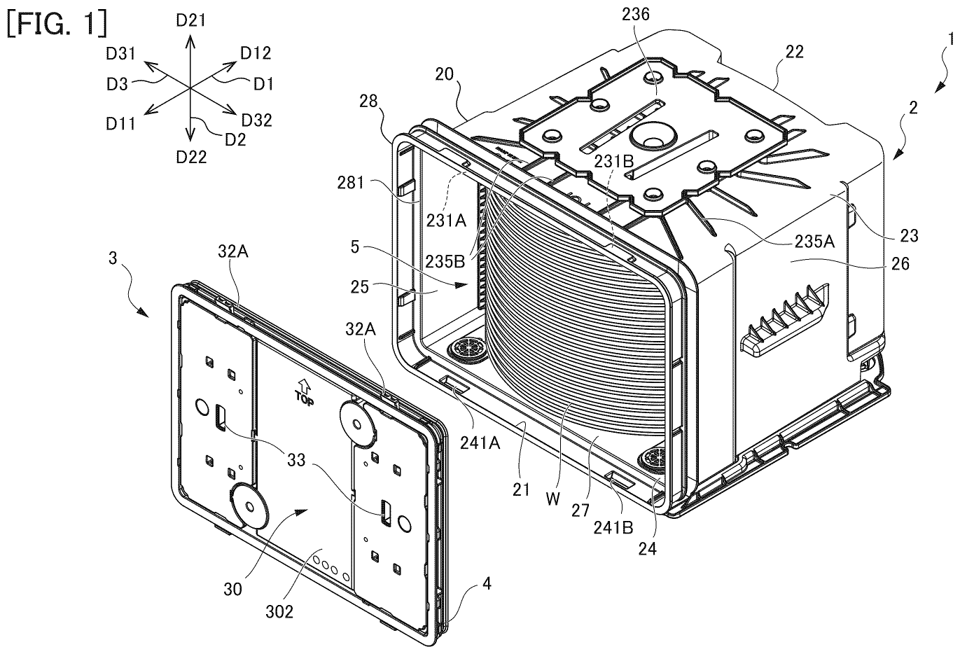

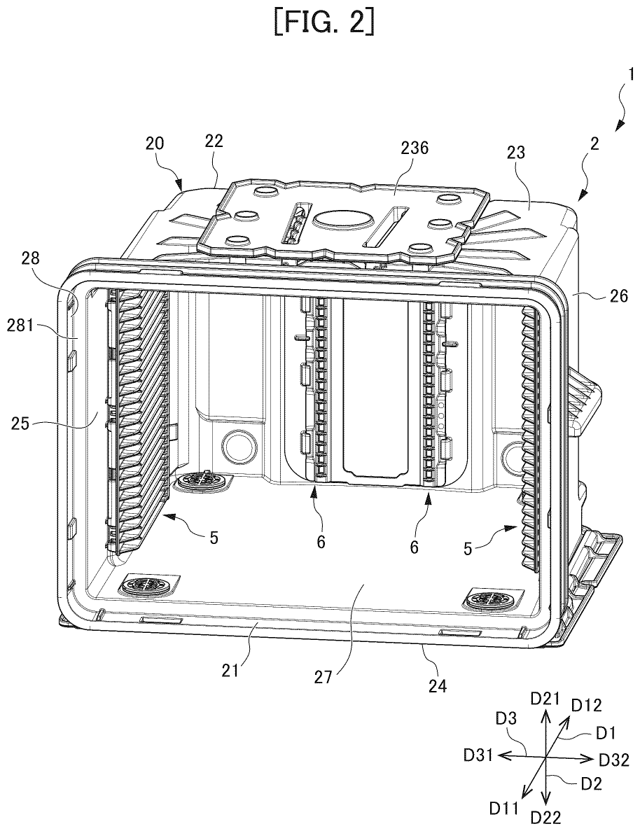

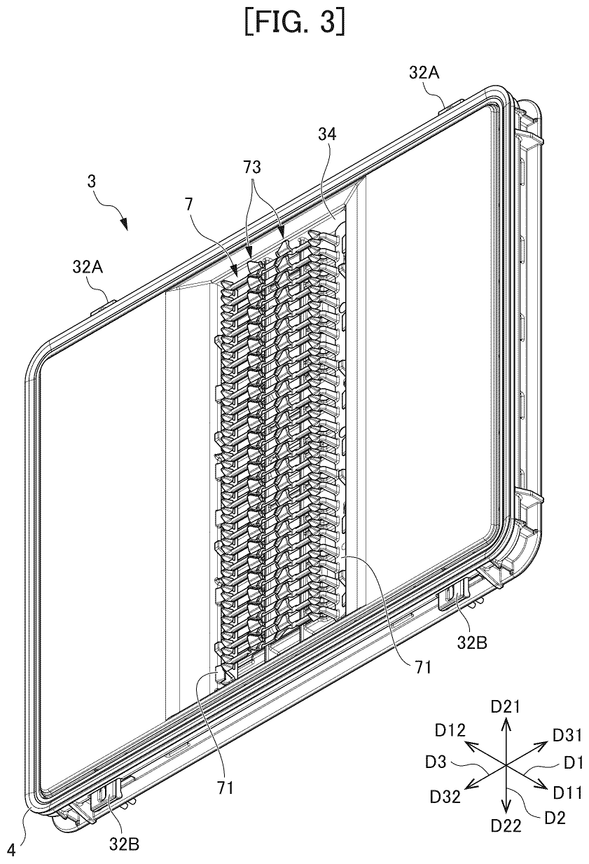

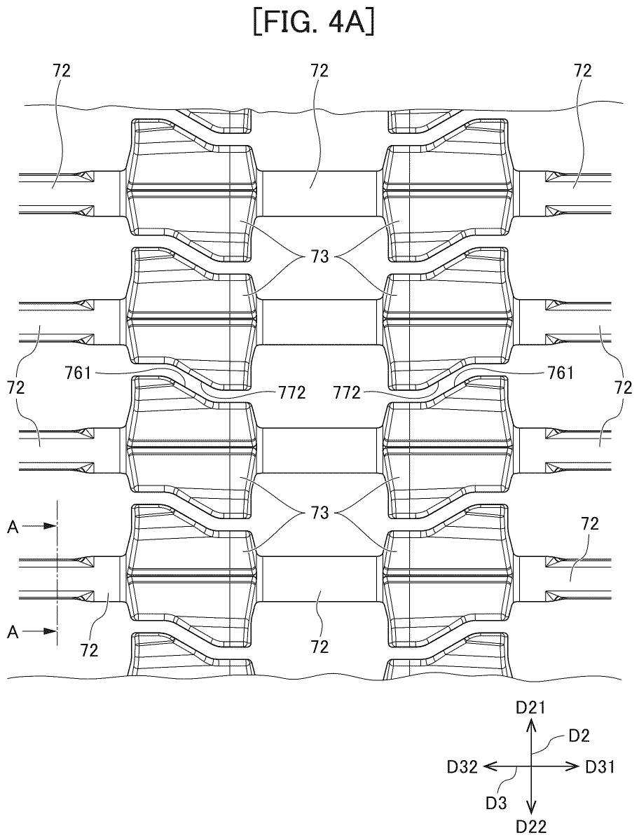

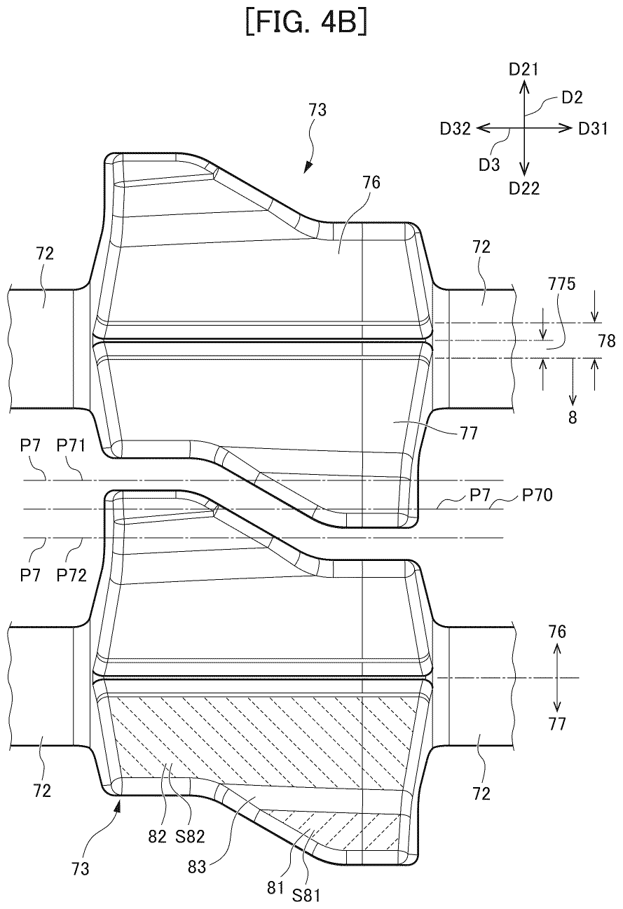

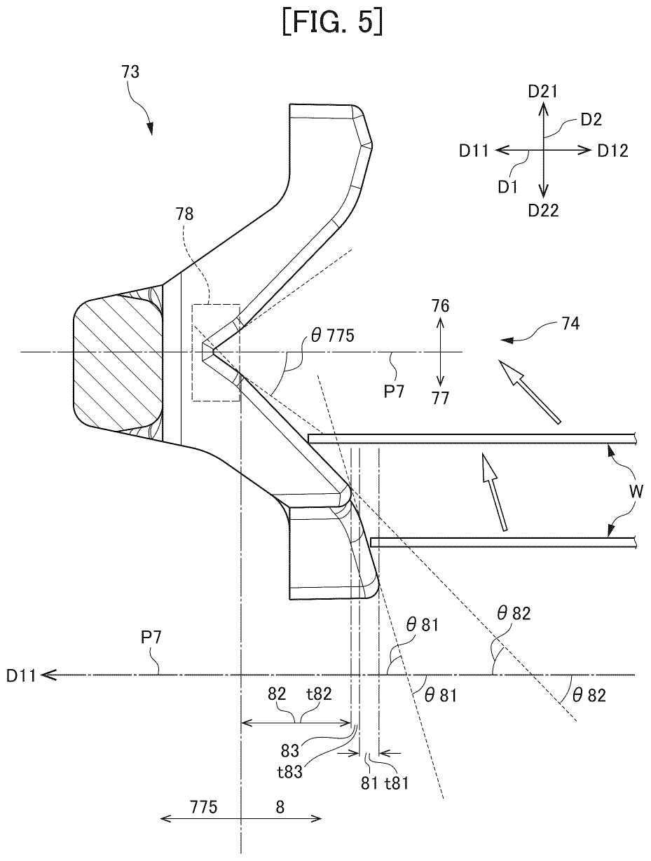

A substrate storing container 1 according to an embodiment of the present invention will be described below with reference to the drawings. FIG. 1 is an exploded perspective view illustrating a state in which substrates W are stored in the substrate storing container 1 according to the embodiment of the present invention. FIG. 2 is a perspective view illustrating a container body 2 in which the substrates W are not stored. FIG. 3 is a perspective view illustrating a lid 3 having a front retainer 7 attached thereto. FIG. 4A is a partial front view (as viewed in a forward direction D11) illustrating lid-side substrate supports 73 of the front retainer 7. FIG. 4B is a partial enlarged view of FIG. 4A. FIG. 5 is a cross-sectional view taken along line A-A in FIG. 4A.

For convenience of description, the direction from the container body 2 (described later) toward the lid 3 (described later) (a direction from upper right toward lower left in FIG. 1) is defined as a forward direction D11, and the direction opposite to the direction D11 is defined as a rearward direction D12. Furthermore, these directions are defined as a forward-rearward direction D1. The direction from a lower wall 24 to an upper wall 23 (described later) (upward direction in FIG. 1) is defined as an upward direction D21, and the direction opposite to the direction D21 is defined as a downward direction D22. Furthermore, these directions are defined as an upward-downward direction D2. The direction from a second side wall 26 to a first side wall 25 (described later) (a direction from lower right toward upper left in FIG. 1) is defined as a left direction D31, and the direction opposite to the direction D31 is defined as a right direction D32. Furthermore, these directions are defined as a left-right direction D3 or a lateral direction D3. The “direction” may be referred to as “side”.

The substrates W stored in the substrate storing container 1 are thin substrates for industrial use, and examples thereof include disk-shaped silicon wafers, disk-shaped glass wafers, and disk-shaped sapphire wafers. Each substrate W of the present embodiment is a silicon wafer having a diameter of 200 mm to 450 mm.

As illustrated in FIGS. 1 to 3, the substrate storing container 1 is for storing the substrates W each composed of the silicon wafer described above, and includes a container body 2, a lid 3, lateral substrate supports 5, back-side substrate supports 6, and a front retainer 7 having lid-side substrate supports 73.

As illustrated in FIGS. 1 and 2, the container body 2 includes a tubular wall 20. One end of the wall 20 on the forward side D11 has a container body opening 21, and the other end of the wall 20 on the rearward side D12 is closed. The container body 2 has a substrate storing space 27 formed therein. The substrate storing space 27 is surrounded and defined by the wall 20. The lateral substrate supports 5 are disposed on portions of the wall 20 that define the substrate storing space 27. The substrate storing space 27 can store therein the plurality of substrates W.

The lateral substrate supports 5 are provided on the wall 20 so as to form counterparts to each other in the left-right direction D3 in the substrate storing space 27. When the container body opening 21 is not closed with the lid 3, the lateral substrate supports 5 contact with lateral portions of edges of the plurality of substrates W and thereby can support the lateral portions of the edges of the plurality of substrates W in a state in which the substrates W adjacent to each other in the upward-downward direction D2 are arranged in parallel and spaced apart from each other by a predetermined interval. The back-side substrate supports 6 are provided in a back side portion (on the rearward side D12) in the container body 2.

The back-side substrate supports 6 are provided on the wall 20 so as to form a counterpart to the front retainer 7 in the substrate storing space 27. The back-side substrate supports 6 contact with rear portions of the edges of the plurality of substrates W and thereby can support the rear portions of the edges of the plurality of substrates W when the container body opening 21 is closed with the lid 3.

The lid 3 is attachable to and detachable from an opening peripheral edge portion 28 that defines the container body opening 21, and can close the container body opening 21. The front retainer 7 is disposed on a portion of the lid 3 that faces the substrate storing space 27 when the container body opening 21 is closed with the lid 3. The front retainer 7 is disposed so as to form a counterpart to the back-side substrate supports 6 in the forward-rearward direction D1 in the substrate storing space 27.

The front retainer 7 contacts with front portions of the edges of the plurality of substrates W and thereby can support the front portions of the edges of the plurality of substrates W when the container body opening 21 is closed with the lid 3. The front retainer 7 cooperates with the back-side substrate supports 6 to hold the plurality of substrates W in a state in which the substrates W adjacent to each other in the upward-downward direction D2 are arranged in parallel and spaced apart from each other by a predetermined interval when the container body opening 21 is closed with the lid 3. Hereinafter, each component will be described in detail. Basically, the substrate storing container 1 is bilaterally symmetrical, and the description regarding one of the left and right halves applies to or is incorporated into the other.

As illustrated in FIG. 1, etc., the wall 20 of the container body 2 includes a back wall 22, an upper wall 23, a lower wall 24, a first side wall 25, and a second side wall 26. The back wall 22, the upper wall 23, the lower wall 24, the first side wall 25, and the second side wall 26 are made of a plastic material, etc., and are configured as a one-piece molding of polycarbonate in the present embodiment.

The first side wall 25 faces the second side wall 26 in the left-right direction D3, and the upper wall 23 faces the lower wall 24 in the upward-downward direction D2. A rear end of the upper wall 23, a rear end of the lower wall 24, a rear end of the first side wall 25, and a rear end of the second side wall 26 are all connected to the back wall 22. A front end of the upper wall 23, a front end of the lower wall 24, a front end of the first side wall 25, and a front end of the second side wall 26 have a positional relationship of being opposite to the back wall 22, and form the opening peripheral edge portion 28 that defines the container body opening 21 having a substantially rectangular shape.

The opening peripheral edge portion 28 is provided at one end of the container body 2, whereas the back wall 22 is located at the other end of the container body 2. The external shape of the container body 2 formed with the outer surface of the wall 20 is a box shape. The inner surface of the wall 20, that is, the inner surface of the back wall 22, the inner surface of the upper wall 23, the inner surface of the lower wall 24, the inner surface of the first side wall 25, and the inner surface of the second side wall 26 surround and define the substrate storing space 27. The container body opening 21 defined by the opening peripheral edge portion 28 communicates with the substrate storing space 27 that is surrounded by the wall 20 and formed in the container body 2. A maximum of twenty-five substrates W can be stored in the substrate storing space 27.

As illustrated in FIGS. 1 and 2, latch engagement recesses 231A, 231B, 241A, and 241B, which are oriented outward with respect to the substrate storing space 27, are formed in portions of the upper wall 23 and the lower wall 24 near the opening peripheral edge portion 28. A total of four latch engagement recesses 231A, 231B, 241A, and 241B are formed in proximity to the left and right ends of the upper wall 23 and the left and right ends the lower wall 24, on a one-to-one basis.

As illustrated in FIGS. 1 and 2, on the outer surface of the upper wall 23, a flange fixing part (not shown) and ribs 235A, 235B are integrally formed with the upper wall 23. The flange fixing part (not shown) is disposed on a center portion of the upper wall 23. A top flange 236 is fixed to the flange fixing part (not shown). The top flange 236 is disposed at the center portion of the upper wall 23. The top flange 236 is a member by means of which the substrate storing container 1 is hooked and hung in an automated wafer transport system (e.g., an AMHS) , a wafer substrate transport cart (e. g., a PGV), or the like.

Some of the ribs 235A extend approximately in the left direction D31 from the top flange 236, and the others of the ribs 235A extend approximately in the right direction D32 from the top flange 236. Some of the ribs 235B extend in the forward direction D11 from the top flange 236, and the others of the ribs 235B extend in the rearward direction D12 from the top flange 236.

The lid 3 is provided with a latch mechanism. The latch mechanism is provided in proximity to the left and right ends of the lid 3. As illustrated in FIGS. 1 to 3, the latch mechanism includes two upper latch parts 32A that can protrude from the upper side of the lid 3 in the upward direction D21, and two lower latch parts 32B that can protrude from the lower side of the lid 3 in the downward direction D22. The two upper latch parts 32A are disposed respectively in proximity to the left and right ends of the upper side of the lid 3, and the two lower latch parts 32B are disposed respectively in proximity to the left and right ends of the lower side of the lid 3.

The outer surface of the lid 3 is provided with operation parts 33. Operating the operation parts 33 from the front side of the lid 3 causes the upper latch parts 32A and the lower latch parts 32B: to protrude respectively from the upper side and the lower side of the lid 3; and not to protrude respectively from the upper side and the lower side of the lid 3. The upper latch parts 32A protrude from the upper side of the lid 3 in the upward direction D21 to engage with the latch engagement recesses 231A, 231B of the container body 2, and the lower latch parts 32B protrude from the lower side of the lid 3 in the downward direction D22 to engage with the latch engagement recesses 241A, 241B of the container body 2, whereby the lid 3 is fastened to the opening peripheral edge portion 28 of the container body 2.

On the inner surface (which is on the rearward side D12) of a lid body 30, a recess 34 that is oriented outward with respect to the substrate storing space 27 (toward the forward side D11) is formed. The front retainer 7 is fixed to the recess 34.

As illustrated in FIG. 3, the lid 3 has a substantially rectangular shape that substantially coincides with the shape of the opening peripheral edge portion 28 of the container body 2. The lid 3 is detachably attachable to the opening peripheral edge portion 28 of the container body 2. When attached to the opening peripheral edge portion 28, the lid 3 can close the container body opening 21. A loop-shaped sealing member 4 is attached to a portion of the inner surface of the lid 3 (the surface on the back side of the lid 3 shown in FIG. 1). This portion faces a surface (sealing surface 281) of a step formed at a position on the rearward side D12 immediately behind the opening edge of the opening peripheral edge portion 28, when the container body opening 21 is closed with the lid 3.

When the lid 3 is attached to the opening peripheral edge portion 28, the sealing member 4 is elastically deformed by being sandwiched between the sealing surface 281 and the inner surface of the lid 3, whereby the lid 3 hermitically closes the container body opening 21. When the lid 3 is detached from the opening peripheral edge portion 28, the substrates W can be loaded into and unloaded from the substrate storing space 27 formed in the container body 2.

As illustrated in FIGS. 3 to 5, the front retainer 7 includes lid-side substrate supports 73, leg parts 72, and vertical frames 71. Lid-side substrate supports 73 corresponding to the same substrate W are coupled to each other in the left-right direction D3 by a leg part 72.

The lid-side substrate supports 73 are arranged such that two lid-side substrate supports 73 form a pair while being spaced apart from each other in the left-right direction D3 by a predetermined distance. In this way, twenty-five pairs of lid-side substrate supports 73 are arranged to form parallel columns extending in the upward-downward direction D2. Each pair of lid-side substrate supports 73 is supported by a leg part 72, which is elastically deformable. Each leg part 72 couples the two lid-side substrate supports 73, 73 arranged in the lateral direction D3. Each leg part 72 extends outward in the lateral direction D3, away from the pair of lid-side substrate supports 73, 73. The vertical frames 71 extending in parallel along the upward-downward direction D2 are integrally formed with the leg parts 72 at outer ends in the lateral direction D3 of the leg parts 72. When the substrates W are stored in the substrate storing space 27 and the lid 3 is closed, the lid-side substrate supports 73 clamp and support front portions of the edges of the substrates W in a state in which the front portions are urged toward the center of the substrate storing space 27 by the elastic force of the leg parts 72.

As illustrated in FIGS. 4A to 5, each lid-side substrate support 73 has an upper inclined surface 76 and a lower inclined surface 77 that form a V-shaped groove 74, which is a concave groove recessed away from the center of the substrate storing space 27. FIGS. 4B and 5 illustrate the lid-side substrate supports 73 on the right side D32.

The upper inclined surface 76 contacts with an edge of a front surface (upper surface) of a substrate W when the container body opening 21 is closed with the lid 3. The lower inclined surface 77 contacts with an edge of a back surface (lower surface) of the substrate W. Specifically, the upper inclined surface 76 is formed of an inclined surface that extends obliquely so as to approach the center of the substrate storing space 27 in the forward-rearward direction D1 as approaching in the upward direction D21. From another perspective, the upper inclined surface 76 is formed of an inclined surface that extends obliquely in the downward direction D22 as approaching in the forward direction D11.

The lower inclined surface 77 is formed of an inclined surface that extends obliquely so as to move away from the center of the substrate storing space 27 in the forward-rearward direction D1 as approaching in the upward direction D21. From another perspective, the lower inclined surface 77 is formed of an inclined surface that extends obliquely in the upward direction D21 as approaching in the forward direction D11. The upper inclined surface 76 and the lower inclined surface 77 form the V-shaped groove 74 that is a concave groove recessed away from the center of the substrate storing space 27. The edge of the front surface or the edge of the back surface of the substrate W comes into contact with the upper inclined surface 76 or the lower inclined surface 77, respectively, when the container body opening 21 is closed with the lid 3.

More specifically, as illustrated in FIG. 5, a forefront of the upper inclined surface 76 and a forefront of the lower inclined surface 77 function as a clamping portion 78 that clamps the edge portion of corresponding one of the plurality of substrates W. From the viewpoint of ensuring the function of clamping a substrate W, the upper inclined surface 76 and the lower inclined surface 77 preferably form a small angle in the clamping portion 78. Similarly, the lower inclined surface 77 and a virtual plane P7 (also referred to as “horizontal plane P7”) orthogonal to the upward-downward direction D2 preferably form a small angle θ (guiding inclination angle).

The lower inclined surface 77 has a clamping surface 775 that forms the clamping portion 78, and a guiding surface 8 that is located more rearward on the rearward side D12 than the clamping surface 775 and guides the substrate W to the clamping portion 78 while allowing the substrate W to slide thereon. From the viewpoint of placing importance on the function of transferring the substrate W to the V-shaped groove 74, it is preferable that a guiding inclination angle θ of the guiding surface 8 is large. On the other hand from the viewpoint of placing importance on the performance of causing the substrate W to slide up along the guiding surface 8, it is preferable that the guiding inclination angle θ of the guiding surface 8 is small (details will be described later). The guiding inclination angle θ (θ81, θ82) of the guiding surface 8 in the forward direction D11 (horizontal plane P7) decreases gradually in multiple steps.

The guiding surface 8 has a first guiding surface 81 on the rearward side D12, a second guiding surface 82 located on the forward side D11 of the first guiding surface 81, and a transition portion 83 located between the first guiding surface 81 and the second guiding surface 82. In the present embodiment, the first guiding surface 81, the second guiding surface 82, and the clamping surface 775 are each a straight flat plane. The transition portion 83 preferably has a shape that smoothly connects the first guiding surface 81 and the second guiding surface 82 to each other. An angle θ82 between the second guiding surface 82 and the horizontal plane P7 is smaller than an angle θ81 between the first guiding surface 81 and the horizontal plane P7. That is, in the present embodiment, the guiding surface 8 is inclined with respect to the forward direction D11 (horizontal plane P7) at the guiding inclination angle θ that decreases in two steps (θ82<θ81).

An angle θ775 between the clamping surface 775 and the horizontal plane P7 is smaller than the angle θ82 between the second guiding surface 82 and the horizontal plane P7 (θ775<θ82).

The angle θ81 formed by the first guiding surface 81 is, for example, 50 to 80 degrees. The angle θ82 formed by the second guiding surface 82 is, for example, 30 to 45 degrees. The angle difference (θ81-θ82) between the angle θ81 formed by the first guiding surface 81 and the angle θ82 formed by the second guiding surface 82 is 5 to 50 degrees.

In the forward-rearward direction D1, a length t82 of the second guiding surface 82 is longer than a length t81 of the first guiding surface 81. The length t82 of the second guiding surface 82 is, for example, 2 mm to 3.3 mm. The length t81 of the first guiding surface 81 is, for example, 0.3 mm to 1 mm. The difference (t82-t81) between the length t82 of the second guiding surface 82 and the length t81 of the first guiding surface 81 is, for example, 1 mm to 3 mm. A length t83 of the transition portion 83 is, for example, 0.3 mm to 0.8 mm, for example.

As illustrated in FIG. 4B, an area S82 of the second guiding surface 82 is larger than an area S81 of the first guiding surface 81 in a rear view as viewed from the rearward side D12 toward the forward side D11. The difference (S82 S81) between the area S82 of the second guiding surface 82 and the area S81 of the first guiding surface 81 is, for example, 10 mm² to 40 mm² .

As illustrated in FIG. 4B, with respect to a pair of lid-side substrate supports 73 adjacent to each other in the upward-downward direction D2, virtual planes P7 (horizontal planes P7) orthogonal to the upward-downward direction D2 pass through one or both of one lid-side substrate support 73 on the upward side D21 and the other lid-side substrate support 73 on the downward side D22. Each virtual plane P7 can also be referred to as (a reference direction of) a direction in which a substrate W spreads (extends). In FIG. 4B, a virtual plane P7 passing through only the lid-side substrate support 73 on the upward side D21 is denoted as a virtual plane P71. A virtual plane P7 passing through only the lid-side substrate support 73 on the downward side D22 is denoted as a virtual plane P72. A virtual plane P7 passing through both the lid-side substrate support 73 on the upward side D21 and the lid-side substrate support 73 on the downward side D22 is denoted as a virtual plane P70.

As illustrated in FIGS. 4A and 4B, when the pair of lid-side substrate supports 73 adjacent to each other in the upward-downward direction D2 is viewed from the forward side D11, a lower end edge 772 of the lower inclined surface 77 of a lid-side substrate support 73 on the upward side D21 and an upper end edge 761 of the upper inclined surface 76 of a lid-side substrate support 73 on the downward side D22 are arranged in parallel and spaced apart from each other. The lower end edge 772 of the lower inclined surface 77 of the lid-side substrate support 73 on the upward side D21 and the upper end edge 761 of the upper inclined surface 76 of the lid-side substrate support 73 on the downward side D22 are inclined in the downward direction D22 as approaching inward in the lateral direction D3. More specifically, the lower end edge 772 of the lower inclined surface 77 of the lid-side substrate support 73 on the upward side D21 and the upper end edge 761 of the upper inclined surface 76 of the lid-side substrate support 73 on the downward side D22 are: substantially parallel to each other in the lateral direction D3 at their end portions in the lateral direction D3; and inclined, on the other hand, in the downward direction D22 as approaching inward in the lateral direction D3 at their central portions in the lateral direction D3.

The substrate storing container 1 of the above-described embodiment exerts the following effects.

The substrate storing container 1 of the embodiment includes: the container body 2 including the tubular wall 20 one end of which is on the forward side D11 and has the container body opening 21, and another end of which is on the rearward side D12 and closed, the container body 2 having the substrate storing space 27 formed therein, the substrate storing space 27 being defined by the inner surface of the wall 20, capable of storing a plurality of substrates W, and communicating with the container body opening 21; the lid 3 attachable to and detachable from the container body opening 21 and capable of closing the container body opening 21; the lid-side substrate supports 73 disposed on a portion of the lid 3 that faces the substrate storing space 27 when the container body opening 21 is closed with the lid 3, the lid-side substrate supports 73 being capable of supporting edges of the plurality of substrates W when the container body opening 21 is closed with the lid 3; and the back-side substrate supports 6 disposed so as to form counterparts to the lid-side substrate supports 73 in the substrate storing space 27, and capable of supporting edges of the plurality of the substrates W, the back-side substrate supports 6 being configured to cooperate with the lid-side substrate supports 73 to support the plurality of substrates W in a state in which the edges of the plurality of substrates W are parallel to each other in the upward-downward direction D2 when the container body opening 21 is closed with the lid 3. Each lid-side substrate support 73 has the upper inclined surface 76 and the lower inclined surface 77 that form the V-shaped groove 74 as a concave groove recessed away from the center of the substrate storing space 27. The foremost portions of the upper inclined surface 76 and the lower inclined surface 77 function as the clamping portion 78 that clamps an edge of a corresponding substrate of the plurality of substrates W. The lower inclined surface 77 has the clamping surface 775 that forms the clamping portion 78, and the guiding surface 8 that is located more rearward on the rearward side D12 than the clamping surface 775 and guides the corresponding substrate W to the clamping portion 78 while allowing the corresponding substrate W to slide thereon. The guiding inclination angle O that is inclined with respect to the forward direction D11 of the guiding surface 8 decreases gradually in multiple steps.

From the viewpoint of placing importance on the function of transferring the substrate W to the V-shaped groove 74, it is preferable that the lower end of the lower inclined surface 77 on the rearward side D12 is positioned as downward as possible on the downward side D22. However, the dimension of the lower inclined surface 77 in the upward-downward direction D2 will be large, when the lower end of the lower inclined surface 77 on the rearward side D12 is positioned on the downward side D22. As a result, the guiding inclination angle O that is inclined with respect to the forward direction D11 of the guiding surface 8 will be large. In the case where the guiding inclination angle θ of the guiding surface 8 is large, the performance of causing the substrate W to slide up along the guiding surface 8 deteriorates. To address such deterioration, according to the embodiment, the guiding inclination angle θ that is inclined with respect to the forward direction D11 of the guiding surface 8 decreases gradually in multiple steps. Accordingly, it is possible that the guiding inclination angle θ (θ81) on the rearward side D12 of the guiding surface 8 is set large, and the lower end of the lower inclined surface 77 on the rearward side D12 is positioned as downward as possible on the downward side D22, such that the function of transferring the substrate W to the V-shaped groove 74 is reinforced. At the same time, it is possible that the guiding inclination angle θ on the forward side D11 of the guiding surface 8 is set small (θ82<θ81), such that the performance of causing the substrate W to slide up along the guiding surface 8 is upgraded. That is, the embodiment makes it possible to achieve both the function of transferring the substrate W to the V-shaped groove 74 and the performance of causing the substrate W to slide up along the guiding surface 8.

In the substrate storing container 1 of the embodiment, the guiding surface 8 has the first guiding surface 81 on the rearward side D12 and the second guiding surface 82 on the forward side D11 of the first guiding surface 81, and the length t82 of the second guiding surface 82 is larger than the length t81 of the first guiding surface 81 in the forward-rearward direction D1. This feature of the embodiment, in which the length t82 of the second guiding surface 82 is large, makes it possible to improve the performance of causing the substrate W to slide up along the guiding surface 8.

In the substrate storing container 1 of the embodiment, the area S82 of the second guiding surface 82 is larger than the area S81 of the first guiding surface 81. This feature of the embodiment, in which the area S82 of the second guiding surface 82 is large, makes it possible to improve the performance of causing the substrate W to slide up along the guiding surface 8.

In the substrate storing container 1 of the embodiment, a virtual plane P7 orthogonal to a pair of lid-side substrate supports 73 adjacent to each other in the upward-downward direction D2 passes through one or both of a lid-side substrate support 73 on the upward side D21 and a lid-side substrate support 73 on the downward side D22. Accordingly, the embodiment makes it possible to avoid a situation in which the substrate W cannot be supported by the lid-side substrate supports 73, as a result of being inserted between the lower end edge 772 of the lower inclined surface 77 of the lid-side substrate support 73 on the upward side D21 and the upper end edge 761 of the upper inclined surface 76 of the lid-side substrate support 73 on the downward side D22.

The present invention is not limited to the embodiment described above, and can be modified within the technical scope described in the claims.

For example, in the embodiment, the guiding inclination angle θ that is inclined with respect to the forward direction D11 of the guiding surface 8 decreases in two steps (θ81>θ82). However, the guiding inclination angle θ may decrease in three or more steps, for example, in three to five steps.

The shapes of the container body 2 and the lid 3 and the number and dimensions of the substrates W that can be stored in the container body 2 are not limited to those described in the above embodiment.

### EXPLANATION OF REFERENCE NUMERALS

1: Substrate storing container
2: Container body
3: Lid
5: Lateral substrate support
6: Back-side substrate support
7: Front retainer
8: Guiding surface
20: Wall
21: Container body opening
27: Substrate storing space
28: Opening peripheral edge portion
73: Lid-side substrate support
74: V-shaped groove
76: Upper inclined surface
77: Lower inclined surface
78: Clamping portion
81: First guiding surface
82: Second guiding surface
761: Upper end edge
772: Lower end edge
775: Clamping surface

1. A substrate storing container, comprising:
a container body including a tubular wall one end of which is on a forward side and has a container body opening, and another end of which is on a rearward side and closed, the container body having a substrate storing space formed therein, the substrate storing space being defined by an inner surface of the wall, capable of storing a plurality of substrates, and communicating with the container body opening;
a lid attachable to and detachable from the container body opening and capable of closing the container body opening;
lid-side substrate supports disposed on a portion of the lid that faces the substrate storing space when the container body opening is closed with the lid, the lid-side substrate supports being capable of supporting edges of the plurality of substrates when the container body opening is closed with the lid; and
back-side substrate supports disposed so as to form counterparts to the lid-side substrate supports in the substrate storing space, and capable of supporting edges of the plurality of the substrates, the back-side substrate supports being configured to cooperate with the lid-side substrate supports to support the plurality of substrates in a state in which the edges of the plurality of substrates are parallel to each other in an upward-downward direction when the container body opening is closed with the lid,
wherein each of the lid-side substrate supports has an upper inclined surface and a lower inclined surface that form a V-shaped groove as a concave groove recessed away from a center of the substrate storing space,
wherein a foremost portion of the upper inclined surface and a foremost portion of the lower inclined surface function as a clamping portion that clamps an edge of a corresponding substrate of the plurality of substrates,
wherein the lower inclined surface has a clamping surface that forms the clamping portion, and a guiding surface that is located more rearward on the rearward side than the clamping surface and guides the corresponding substrate to the clamping portion while allowing the corresponding substrate to slide thereon,
wherein an angle between the clamping surface and a forward direction is smaller than an angle between the guiding surface and the forward direction, and
wherein a guiding inclination angle that is inclined with respect to the forward direction of the guiding surface decreases gradually in multiple steps.

2. The substrate storing container according to claim 1, wherein the guiding surface has a first guiding surface on the rearward side and a second guiding surface on the forward side of the first guiding surface, and
wherein the second guiding surface has a larger length than the first guiding surface in a forward-rearward direction.

3. The substrate storing container according to claim 2, wherein the second guiding surface has a larger area than the first guiding surface.

4. The substrate storing container according to claim 1, wherein a virtual plane orthogonal to a pair of lid-side substrate supports adjacent to each other in the upward-downward direction passes through one or both of a lid-side substrate support on the upward side and a lid-side substrate support on a downward side.

5. The substrate storing container according claim 1, wherein when the pair of lid-side substrate supports adjacent to each other in the upward-downward direction is viewed from the forward side, a lower end edge of the lower inclined surface of the lid-side substrate support on the upward side and an upper end edge of the upper inclined surface of the lid-side substrate support on the downward side are arranged in parallel and spaced apart from each other, and are inclined in the downward direction as approaching inward in a lateral direction.
